(19) United States
(12) Patent Application Publication
(10) Pub. No.: US 2025/0246416 A1
(43) Pub. Date: Jul. 31, 2025

(54) SUBSTRATE SUPPORT AND PLASMA PROCESSING APPARATUS

(71) Applicant: Tokyo Electron Limited, Tokyo (JP)

(72) Inventors: Shin YAMAGUCHI, Kurokawa-gun (JP); Daiki SATOH, Kurokawa-gun (JP)

(73) Assignee: Tokyo Electron Limited, Tokyo (JP)

(21) Appl. No.: 19/183,966

(22) Filed: Apr. 21, 2025

Related U.S. Application Data
(63) Continuation of application No. PCT/JP2023/037424, filed on Oct. 16, 2023.
(60) Provisional application No. 63/418,682, filed on Oct. 24, 2022.

(51) Int. Cl. H01J 37/32

(52) U.S. Cl. CPC H01J 37/32724; H01J 37/32467; H01J 37/32568; H01J 2237/2007

(57) ABSTRACT

In one embodiment, a substrate support comprises a support body, a base, and a ceramic member. The support body is configured to support an object thereon. The object includes a substrate. The support body includes a dielectric portion and a bias electrode. The support body provides a first through-hole penetrating from an upper surface of the dielectric portion to a lower surface of the dielectric portion. The base provides a second through-hole communicating with the first through-hole. The ceramic member has permeability allowing a heat-transfer gas to pass therethrough. The ceramic member is filled in an upper end of the first through-hole. The ceramic member is positioned to set a distance between a lower end thereof and the bias electrode to be smaller than a distance between an upper end thereof and the bias electrode, in a direction in which a central axis of the first through-hole extends.

### CROSS-REFERENCE TO RELATED APPLICATIONS

This application is a continuation application of PCT Application No. PCT/JP2023/037424, filed on Oct. 16, 2023, which claims the benefit of priority from U.S. Provisional Patent Application 63/418,682, filed on Oct. 24, 2022. The entire contents of the above listed PCT and priority applications are incorporated herein by reference.

### BACKGROUND

### Field

Exemplary embodiments of the present disclosure relate to a substrate support and a plasma processing apparatus.

### Description of the Related Art

A plasma processing apparatus is used in plasma processing to be performed on a substrate. Japanese Unexamined Patent Publication No. 2019-220555 as follows discloses one type of plasma processing apparatus. The plasma processing apparatus disclosed in Patent Literature 1 includes a chamber and a substrate support. The substrate support includes an upper surface including a support surface on which the substrate is placed. The substrate support provides through-holes configured to supply a heat-transfer gas into a gap between the substrate placed on the support surface and the upper surface of the substrate support.

### SUMMARY

In one embodiment, a substrate support includes a support body, a base, and a ceramic member. The support body is configured to support an object thereon. The object includes a substrate. The support body includes a dielectric portion and a bias electrode. The dielectric portion has an upper surface and a lower surface opposite the upper surface. The upper surface includes a support surface facing the object. The bias electrode disposed in the dielectric portion. The support body provides a first through-hole penetrating from the upper surface to the lower surface. The base provides a second through-hole communicating with the first through-hole. The base is configured to support the support body thereon. The ceramic member has permeability allowing a heat-transfer gas to pass therethrough. The ceramic member is filled in an upper end of the first through-hole. The ceramic member is positioned to set a distance between a lower end thereof and the bias electrode to be smaller than a distance between an upper end thereof and the bias electrode, in a direction in which a central axis of the first through-hole extends.

### BRIEF DESCRIPTION OF DRAWINGS

FIG. 1 is a block diagram of a computer-based system that functions as a controller of a plasma processing apparatus according to an exemplary embodiment.

FIG. 2 is a diagram for describing a configuration example of a plasma processing system.

FIG. 3 is a diagram for describing a configuration example of a capacitively coupled plasma processing apparatus.

FIG. 4 is a partially enlarged sectional view of a substrate support according to an exemplary embodiment.

FIG. 5 is a partially enlarged sectional view of a substrate support according to an exemplary embodiment.

### DETAILED DESCRIPTION

In the following description, with reference to the drawings, the same reference numbers are assigned to the same components or to similar components having the same function, and overlapping description is omitted.

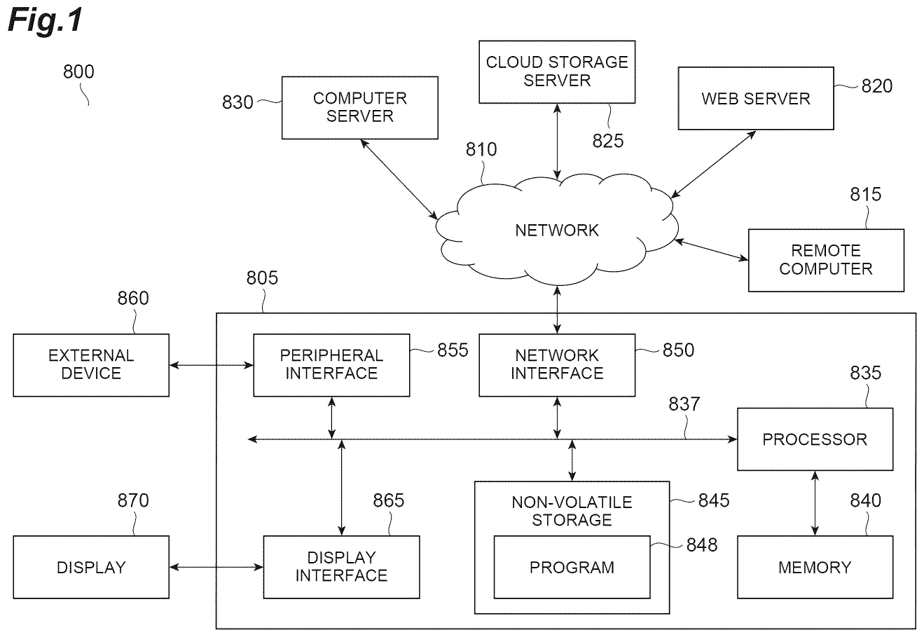

FIG. 1 is a block diagram of a computer-based system that functions as a controller of a plasma processing device according to an exemplary embodiment.

Control aspects of the present disclosure may be embodied as a system, a method, and/or a computer program product. The computer program product may include a computer readable storage medium on which computer readable program instructions are recorded that may cause one or more processors to carry out aspects of the embodiment.

The computer readable storage medium may be a tangible device that can store instructions for use by an instruction execution device (processor). The computer readable storage medium may be, for example, but is not limited to, an electronic storage device, a magnetic storage device, an optical storage device, an electromagnetic storage device, a semiconductor storage device, or any appropriate combination of these devices. A non-exhaustive list of more specific examples of the computer readable storage medium includes each of the following (and appropriate combinations): flexible disk, hard disk, solid-state drive (SSD), random access memory (RAM), read-only memory (ROM), erasable programmable read-only memory (EPROM or Flash), static random access memory (SRAM), compact disc (CD or CD-ROM), digital versatile disk (DVD) and memory card or stick. A computer readable storage medium, as used in this disclosure, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described in this disclosure can be downloaded to an appropriate computing or processing device from a computer readable storage medium or to an external computer or external storage device via a global network (i.e., the Internet), a local area network, a wide area network and/or a wireless network. The network may include copper transmission wires, optical communication fibers, wireless transmission, routers, firewalls, switches, gateway computers and/or edge servers. A network adapter card or network interface in each computing or processing device may receive computer readable program instructions from the network and forward the computer readable program instructions for storage in a computer readable storage medium within the computing or processing device.

Computer readable program instructions for carrying out operations of the present disclosure may include machine language instructions and/or microcode, which may be compiled or interpreted from source code written in any combination of one or more programming languages, including assembly language, Basic, Fortran, Java, Python, R, C, C++, C#or similar programming languages. The computer readable program instructions may execute entirely on a user's personal computer, notebook computer, tablet, or smartphone, entirely on a remote computer or computer server, or any combination of these computing devices. The remote computer or computer server may be connected to the user's device or devices through a computer network, including a local area network or a wide area network, or a global network (i.e., the Internet). In some embodiments, electronic circuitry including, for example, programmable logic circuitry, field-programmable gate arrays (FPGA), or programmable logic arrays (PLA) may execute the computer readable program instructions by using information from the computer readable program instructions to configure or customize the electronic circuitry, in order to perform aspects of the present disclosure.

Aspects of the present disclosure are described herein with reference to flow diagrams and block diagrams of methods, apparatus (systems), and computer program products according to embodiments of the disclosure. It will be understood by those skilled in the art that each block of the flow diagrams and block diagrams, and combinations of blocks in the flow diagrams and block diagrams, can be implemented by computer readable program instructions.

The computer readable program instructions that may implement the systems and methods described in this disclosure may be provided to one or more processors (and/or one or more cores within a processor) of a general purpose computer, special purpose computer, or other programmable apparatus to produce a machine, such that the instructions, which execute via the processor of the computer or other programmable apparatus, create a system for implementing the functions specified in the flow diagrams and block diagrams in the present disclosure. These computer readable program instructions may also be stored in a computer readable storage medium that can direct a computer, a programmable apparatus, and/or other devices to function in a particular manner, such that the computer readable storage medium having stored instructions is an article of manufacture including instructions which implement aspects of the functions specified in the flow diagrams and block diagrams in the present disclosure.

The computer readable program instructions may also be loaded onto a computer, other programmable apparatus, or other device to cause a series of operational steps to be performed on the computer, other programmable apparatus or other device to produce a computer implemented process, such that the instructions which execute on the computer, other programmable apparatus, or other device implement the functions specified in the flow diagrams and block diagrams in the present disclosure.

FIG. 1 is a functional block diagram illustrating a networked system 800 of one or more networked computers and servers. In an embodiment, the hardware and software environment illustrated in FIG. 1 may provide an exemplary platform for implementation of the software and/or methods according to the present disclosure.

Referring to FIG. 1, a networked system 800 may include, but is not limited to, computer 805, network 810, remote computer 815, web server 820, cloud storage server 825 and computer server 830. In some embodiments, multiple instances of one or more of the functional blocks illustrated in FIG. 1 may be employed.

Additional detail of computer 805 is shown in FIG. 1. The functional blocks illustrated within computer 805 are provided only to establish exemplary functionality and are not intended to be exhaustive. And while details are not provided for remote computer 815, web server 820, cloud storage server 825 and computer server 830, these other computers and devices may include similar functionality to that shown for computer 805.

Computer 805 may be a personal computer (PC), a desktop computer, laptop computer, tablet computer, netbook computer, a personal digital assistant (PDA), a smart phone, or any other programmable electronic device capable of communicating with other devices on network 810.

Computer 805 may include processor 835, bus 837, memory 840, non-volatile storage 845, network interface 850, peripheral interface 855 and display interface 865. Each of these functions may be implemented, in some embodiments, as individual electronic subsystems (integrated circuit chip or combination of chips and associated devices), or, in other embodiments, some combination of functions may be implemented on a single chip (sometimes called a system on chip or SoC).

Processor 835 may be one or more single or multi-chip microprocessors, such as those designed and/or manufactured by Intel

Corporation, Advanced Micro Devices, Inc. (AMD), Arm Holdings (Arm), Apple Computer, etc. Examples of microprocessors include Celeron, Pentium, Core i3, Core i5 and Core i7 from Intel Corporation; Opteron, Phenom, Athlon, Turion and Ryzen from AMD; and Cortex-A, Cortex-R and Cortex-M from Arm.

Bus 837 may be a proprietary or industry standard high-speed parallel or serial peripheral interconnect bus, such as ISA, PCI, PCI Express (PCI-e), AGP, and the like.

Memory 840 and non-volatile storage 845 may be computer-readable storage media. Memory 840 may include any suitable volatile storage devices such as Dynamic Random Access Memory (DRAM) and Static Random Access Memory (SRAM). Non-volatile storage 845 may include one or more of the following: flexible disk, hard disk, solid-state drive (SSD), read-only memory (ROM), erasable programmable read-only memory (EPROM or Flash), compact disc (CD or CD-ROM), digital versatile disk (DVD) and memory card or stick.

Program 848 may be a collection of machine readable instructions and/or data that is stored in non-volatile storage 845 and is used to create, manage and control certain software functions that are discussed in detail elsewhere in the present disclosure and illustrated in the drawings. In some embodiments, memory 840 may be considerably faster than non-volatile storage 845. In such embodiments, program 848 may be transferred from non-volatile storage 845 to memory 840 prior to execution by processor 835.

Computer 805 may be capable of communicating and interacting with other computers via network 810 through network interface 850. Network 810 may be, for example, a local area network (LAN), a wide area network (WAN) such as the Internet, or a combination of the two, and may include wired, wireless, or fiber optic connections. In general, network 810 can be any combination of connections and protocols that support communications between two or more computers and related devices.

Peripheral interface 855 may allow for input and output of data with other devices that may be connected locally with computer 805. For example, peripheral interface 855 may provide a connection to external devices 860. External devices 860 may include devices such as a keyboard, a mouse, a keypad, a touch screen, and/or other suitable input devices. External devices 860 may also include portable computer-readable storage media such as, for example, thumb drives, portable optical or magnetic disks, and memory cards. Software and data used to practice embodiments of the present disclosure, for example, program 848, may be stored on such portable computer-readable storage media. In such embodiments, software may be loaded onto non-volatile storage 845 or, alternatively, directly into memory 840 via peripheral interface 855. Peripheral interface 855 may use an industry standard connection, such as RS-232 or Universal Serial Bus (USB), to connect with external devices 860.

Display interface 865 may connect computer 805 to display 870. Display 870 may be used, in some embodiments, to present a command line or graphical user interface to a user of computer 805. Display interface 865 may connect to display 870 using one or more proprietary or industry standard connections, such as VGA, DVI, DisplayPort and HDMI.

As described above, network interface 850, provides for communications with other computing and storage systems or devices external to computer 805. Software programs and data discussed herein may be downloaded from, for example, remote computer 815, web server 820, cloud storage server 825 and computer server 830 to non-volatile storage 845 through network interface 850 and network 810. Furthermore, the systems and methods described in this disclosure may be executed by one or more computers connected to computer 805 through network interface 850 and network 810. For example, in some embodiments the systems and methods described in this disclosure may be executed by remote computer 815, computer server 830, or a combination of the interconnected computers on network 810.

Data, datasets and/or databases employed in embodiments of the systems and methods described in this disclosure may be stored and or downloaded from remote computer 815, web server 820, cloud storage server 825 and computer server 830.

Circuitry as used in the present application can be defined as one or more of the following: an electronic component (such as a semiconductor device), multiple electronic components that are directly connected to one another or interconnected via electronic communications, a computer, a network of computer devices, a remote computer, a web server, a cloud storage server, a computer server. For example, each of the one or more of the computer, the remote computer, the web server, the cloud storage server, and the computer server can be encompassed by or may include the circuitry as a component(s) thereof. In some examples, multiple instances of one or more of these components may be employed, wherein each of the multiple instances of the one or more of these components are also encompassed by or include circuitry. In some examples, the circuitry represented by the networked system may include a serverless computing system corresponding to a virtualized set of hardware resources. The circuitry represented by the computer may be a personal computer (PC), a desktop computer, a laptop computer, a tablet computer, a netbook computer, a personal digital assistant (PDA), a smart phone, or any other programmable electronic device capable of communicating with other devices on the network. The circuitry may be a general purpose computer, special purpose computer, or other programmable apparatus as described herein that includes one or more processors. Each processor may be one or more single or multi-chip microprocessors. Processors are considered processing circuitry or circuitry as they include transistors and other circuitry therein. The circuitry may implement the systems and methods described in this disclosure based on computer-readable program instructions provided to the one or more processors (and/or one or more cores within a processor) of one or more of the general purpose computer, special purpose computer, or other programmable apparatus described herein to produce a machine, such that the instructions, which execute via the one or more processors of the programmable apparatus that is encompassed by or includes the circuitry, create a system for implementing the functions specified in the flow diagrams and block diagrams in the present disclosure. Alternatively, the circuitry may be a preprogrammed structure, such as a programmable logic device, application specific integrated circuit, or the like, and is/are considered circuitry regardless if used in isolation or in combination with other circuitry that is programmable, or preprogrammed.

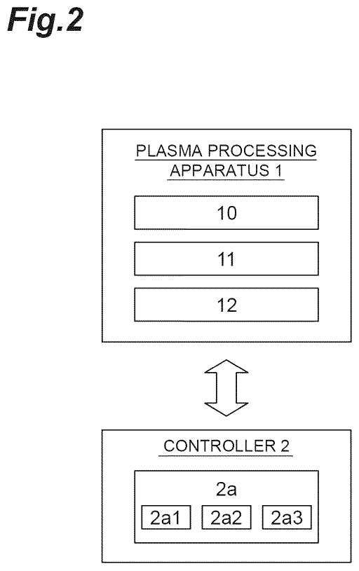

FIG. 2 illustrates an example configuration of a plasma processing system. In an embodiment, the plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support unit 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various operations described in this disclosure. The controller 2 may be configured to control individual components of the plasma processing apparatus 1 such that these components execute the various operations. In an embodiment, the controller 2 may be partially or entirely incorporated into the plasma processing apparatus 1. In an example, the controller 2 may include a computer 2a. In an example, the computer 2a may include a processor (or CPU: Central Processing Unit) 2al, a storage 2a2, and a communication interface 2a3. The processor 2al may be configured to perform various controlling operations in accordance with a program stored in the storage 2a2. The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

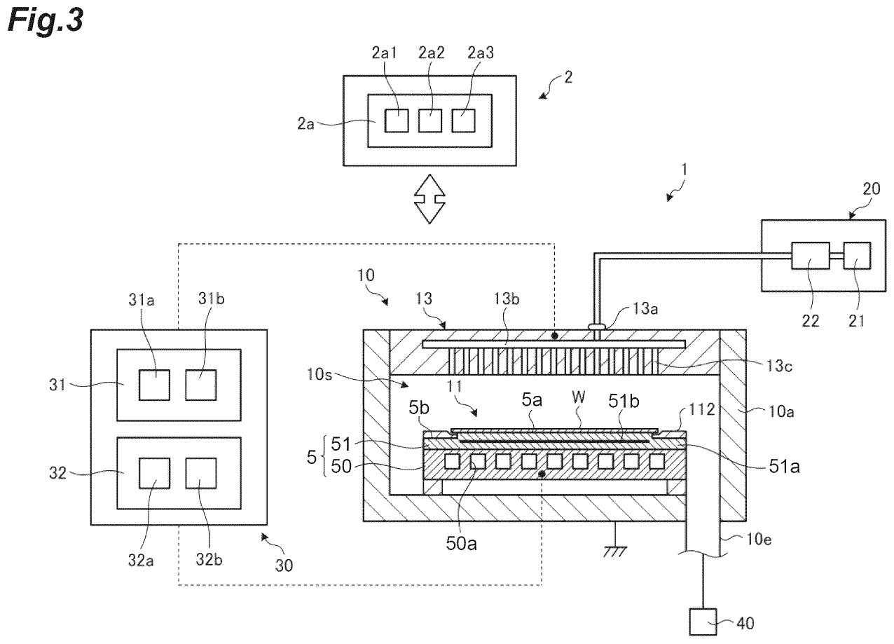

An example configuration of a capacitively coupled plasma processing apparatus, which is an example of the plasma processing apparatus 1, will now be described. FIG. 3 illustrates an example configuration of the capacitively coupled plasma processing apparatus.

The capacitively coupled plasma processing apparatus 1 includes a plasma processing chamber 10, a gas supply 20, a power supply system 30, and a gas exhaust system 40. The plasma processing apparatus 1 further includes a substrate support unit 11 and a gas introduction unit. The gas introduction unit is configured to introduce at least one process gas into the plasma processing chamber 10. The gas introduction unit includes a showerhead 13. The substrate support unit 11 is disposed in a plasma processing chamber 10. The showerhead 13 is disposed above the substrate support unit 11. In an embodiment, the showerhead 13 configures at least a part of the ceiling of the plasma processing chamber 10. The plasma processing chamber 10 has a plasma processing space 10s that is defined by the showerhead 13, the sidewall 10a of the plasma processing chamber 10, and the substrate support unit 11. The sidewall 10a is grounded. The showerhead 13 and the substrate support unit 11 are electrically insulated from the housing of the plasma processing chamber 10.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes a conductive member. The conductive member of the showerhead 13 functions as an upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may include, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

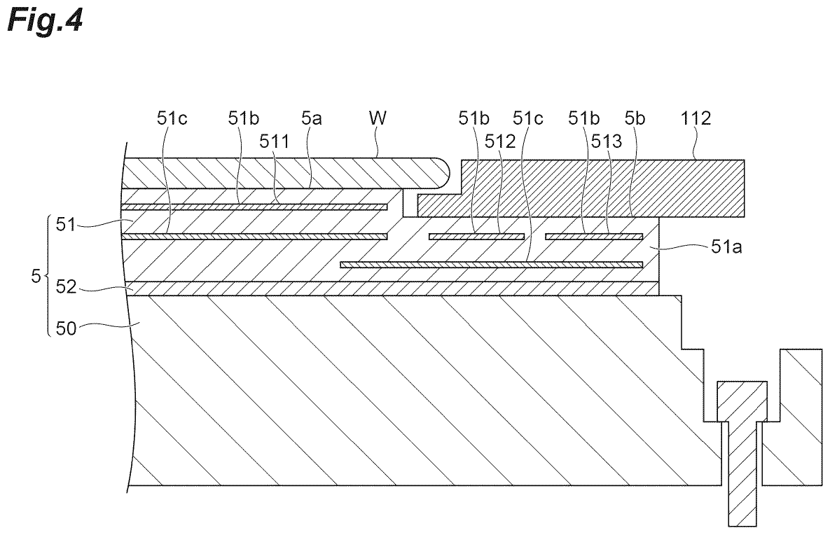

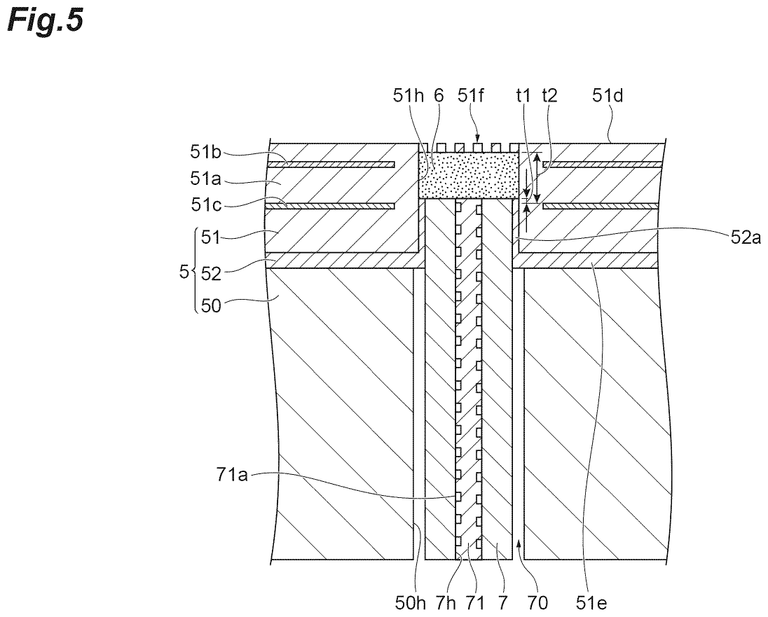

FIG. 4 and FIG. 5 are partially enlarged sectional views of a substrate support according to an exemplary embodiment. Hereinafter, details of a substrate support 5 will be described with reference to FIGS. 3 to 5.

The substrate support unit 11 includes a substrate support 5. The substrate support 5 includes a base 50 and a support body 51. The support body 51 is configured to support an object thereon. The object includes a substrate W. A wafer is an example of the substrate W. The object may include the ring assembly 112.

The substrate support 5 includes a central region 5a for supporting the substrate W and an annular region 5b for supporting the ring assembly 112. The annular region 5b of the substrate support 5 surrounds the central region 5a of the substrate support 5 in plan view. The substrate W is disposed on the central region 5a of the substrate support 5, and the ring assembly 112 is disposed on the annular region 5b of the substrate support 5 to surround the substrate W on the central region 5a of the substrate support 5. Thus, an upper surface of the central region 5a includes a substrate support surface for supporting the substrate W, while an upper surface of the annular region 5b includes a ring support surface for supporting the ring assembly 112.

In addition, other members, such as an annular support body or an annular insulating member, surrounding the support body 51 may include the annular region 5b. In this case, the ring assembly 112 may be disposed on the annular support body or the annular insulating member, or may be disposed on both the support body 51 and the annular insulating member.

The ring assembly 112 includes one or a plurality of annular members. In an embodiment, the one or a plurality of annular members include one or a plurality of edge rings and at least one covering. The edge ring is made of a conductive material or an insulating material, and the covering is made of an insulating material.

The base 50 supports the support body 51 thereon. The base 50 may include a conductive member. The conductive member included in the base 50 can function as a lower electrode. The support body 51 includes a dielectric portion 51a and a bias electrode 51c (first electrode). The bias electrode 51c is disposed in the dielectric portion 51a. In an example, the support body 51 is an electrostatic chuck.

The bias electrode 51c is electrically coupled to the RF source 31 and/or DC source 32. The bias electrode 51c can function as a lower electrode. The bias electrode 51c is supplied with the bias RF signal and/or the DC signal. The bias electrode 51c may be supplied with radio frequency power HF from the RF source 31, or may be supplied with radio frequency power LF from the RF source 31. In an example, the radio frequency power HF has a frequency in a range of 27 MHz or more and 100 MHz or less. In an example, the radio frequency power LF has a frequency in a range of 400 kHz or more and 13.56 MHz or less. The bias electrode 51c may be supplied with the radio frequency power HF and the radio frequency power LF simultaneously. The bias RF signal and/or DC signal supplied to the bias electrode 51c may be a pulse wave.

In an embodiment, the support body 51 may include an electrostatic electrode 51b (second electrode). The electrostatic electrode 51b is disposed in the dielectric portion 51a. In an example, the electrostatic electrode 51b may be disposed above the bias electrode 51c. The support body 51 may include a plurality of electrostatic electrodes 51b. In the example shown in FIG. 4, the support body 51 includes a first electrostatic electrode 511 as the electrostatic electrode 51b in the central region 5a, and includes a second electrostatic electrode 512 and a third electrostatic electrode 513 as the electrostatic electrodes 51b in the annular region 5b. The second electrostatic electrode 512 is positioned between the first electrostatic electrode 511 and the third electrostatic electrode 513. The second electrostatic electrode 512 and the third electrostatic electrode 513 are used as a pair of electrodes for a bipolar electrostatic chuck. The support body 51 need not include the electrostatic electrode 51b. The bias electrode 51c may function as an electrostatic electrode.

The substrate support unit 11 may also include a temperature adjusting module that is configured to adjust at least one of the support body 51, the ring assembly 112, and the substrate W to a target temperature. The temperature adjusting module may include a heater, a heat transfer medium, a flow path 50a, or any combination thereof. A heat transfer fluid, such as brine or gas, flows into the flow path 50a. In an embodiment, the flow path 50a is formed in the base 50, one or a plurality of heaters are disposed in the dielectric portion 51a of the support body 51. The one or a plurality of heaters may be disposed below the bias electrode 51c.

The description will be made below with reference to FIG. 5. The dielectric portion 51a includes an upper surface 51d and a lower surface 51e opposite to the upper surface 51d. The upper surface 51d includes a support surface. The support surface faces the substrate W (an example of an object). The support surface may include a substrate support surface of the central region 5a and a ring support surface of the annular region 5b. In an example, in a case where a plurality of protrusions are formed on the surface of the central region 5a, the upper surface 51d includes an upper surface of each of the plurality of protrusions that configure the support surface (substrate support surface), a side surface of each of the plurality of protrusions, and a bottom surface between the plurality of protrusions.

The support body 51 provides a first through-hole 51h. The first through-hole 51h penetrates from the upper surface 51d to the lower surface 51e. The first through-hole 51h may include at least one pore 51f. The at least one pore 51f is formed in the upper surface 51d. In an example, the number of the number 51f of at least one pore is 1 or more and 30 or less. In an example, the diameter of at least one pore 51f is 0.1 mm or more and 0.5 mm or less. The length of at least one pore 51f is 0.1 mm or more and 1.0 mm or less. The base 50 provides a second through-hole 50h. The second through-hole communicates with the first through-hole 51h. The central axis of the second through-hole 50h may overlap with the central axis of the first through-hole 51h.

The substrate support 5 includes a ceramic member 6. The ceramic member 6 has permeability that allows the heat-transfer gas to pass therethrough. In an example, the heat-transfer gas is helium gas. The ceramic member 6 is filled at the upper end of the first through-hole 51h. The ceramic member 6 may face a portion of the dielectric portion 51a that provides at least one pore 51f. The ceramic member 6 may be filled so as to be connected to at least one pore 51f. The first through-hole 51h is configured to allow the heat-transfer gas to be supplied to a gap between the substrate W placed on the support surface and the upper surface 51d. For example, the first through-hole 51h is configured to allow the heat-transfer gas to be supplied to a gap between the ring assembly 112 placed on the support surface and the upper surface 51d via the ceramic member 6. The length of the ceramic member 6 in a direction in which the central axis of the first through-hole 51h extends is 1 mm or more and 5 mm or less.

The ceramic member 6 is positioned to set a distance t1 between a lower end thereof and the bias electrode 51c to be smaller than a distance t2 between an upper end thereof and the bias electrode 51c, in the direction in which the central axis of the first through-hole 51h extends. Since the ceramic member 6 fills a space above the bias electrode 51c of the first through-hole 51h, abnormal discharge in the space in the first through-hole 51h is suppressed. Therefore, the abnormal discharge in the substrate support 5 is suppressed. The shortest distance between the surface defining the first through-hole 51h and the bias electrode 51c may be 1.0 mm or less, or 2.0 mm or less.

In an embodiment, the lower end of the ceramic member 6 may be positioned above the bias electrode 51c. In a case where the lower end of the ceramic member 6 is positioned above the bias electrode 51c, in an embodiment, the lower end of the ceramic member 6 may be positioned at a distance of 0.1 mm or more from the bias electrode 51c in the direction in which the central axis of the first through-hole 51h extends. That is, the distance t1 between the lower end of the ceramic member 6 and the bias electrode 51c may be 0.1 mm or more. The distance t1 may be 0.1 mm or more and 4.0 mm or less. Since the total length of the ceramic member 6 in the direction in which the central axis of the first through-hole 51h extends can be shortened, the pressure loss of the heat-transfer gas in the ceramic member 6 can be reduced.

In an embodiment, the ceramic member 6 may be a porous member or a multi-tube member that provides a plurality of through-holes penetrating from the upper end thereof to the lower end thereof. In the example shown in FIG. 5, the ceramic member 6 is a porous member. In an embodiment, a ratio of a volume of all pores to a volume of the porous member may be 40% or more. The ceramic member is made of, for example, aluminum oxide or silicon carbide.

In an embodiment, the substrate support 5 further includes an insulating member 7 (first insulating member). The insulating member 7 has an insulating property. In an example, the insulating member 7 is made of aluminum oxide. The insulating member 7 may be made of quartz. The insulating member 7 is disposed in the first through-hole 51h and the second through-hole 50h. The ceramic member 6 may be supported by the insulating member 7 without being bonded to the support body 51. The insulating member 7 provides a third through-hole 7h connected to the ceramic member 6. The insulating member 7 may have a cylindrical shape. In an example, the diameter of the third through-hole is 1 mm or more and 3 mm or less. For example, the third through-hole 7h is configured to allow the heat-transfer gas to be supplied to the ceramic member 6. A supply source of the heat-transfer gas may be connected to a lower end of the third through-hole 7h. With the insulating member 7, since the insulating member 7 is interposed in the second through-hole 50h, abnormal discharge in the second through-hole 50h is suppressed. In addition, since the insulating member 7 is interposed in the first through-hole 51h, abnormal discharge in the first through-hole 51h is further suppressed.

In an embodiment, the substrate support 5 may further include an insulating member 7 (second insulating member). The insulating member 71 is disposed in the third through-hole 7h. The insulating member 71 provides a gap connected to the ceramic member 6 in the third through-hole 7h. The gap connected to the ceramic member 6 in the third through-hole 7h is configured to allow the heat-transfer gas to pass through the gap. In an example, the insulating member 71 is made of fluororesin. With the insulating member 71, since the insulating member 71 is interposed in the third through-hole 7h, abnormal discharge in the third through-hole 7h is suppressed.

In an embodiment, the insulating member 71 provides, on a surface thereof, a groove 71a that spirally extends around the central axis of the third through-hole. The gap connected to the ceramic member 6 in the third through-hole 7h is formed between a surface of the insulating member 71 defining the groove 71a and a surface of the insulating member 7 defining the third through-hole 7h. The maximum width of the insulating member 71 may be smaller than the maximum width of the third through-hole 7h. In this case, the insulating member 71 can provide the gap connected to the ceramic member 6 in the third through-hole 7h without providing the groove 71a. The gap connected to the ceramic member 6 in the third through-hole 7h can be formed between the surface of the insulating member 71 and the surface of the insulating member 7 defining the third through-hole 7h.

In an embodiment, the substrate support 5 further includes a first bonding material 52 and a second bonding material 52a. The first bonding material 52 is interposed between the support body 51 and the base 50 and bonds the support body 51 and the base 50 to each other. The second bonding material 52a is interposed between the insulating member 7 and the support body 51 in the first through-hole 51h and bonds the insulating member 7 and the support body 51 to each other. Each of the first bonding material 52 and the second bonding material 52a is, for example, a cured adhesive. In a case where a linear expansion coefficient of the support body 51 and a linear expansion coefficient of the insulating member 7 are close to each other, peeling of the insulating member 7 from the support body 51 can be suppressed.

In an embodiment, the maximum width of the second through-hole 50h is larger than the maximum width of the first through-hole 51h. In an example, the maximum width of the first through-hole 51h may be 3 mm or more and 5 mm or less, and the maximum width of the second through-hole 50h may be 4 mm or more and 6 mm or less. In an embodiment, a gap 70 may be formed between a surface of the base 50 defining the second through-hole 50h and the insulating member 7. The insulating member 7 may be in non-contact with the base 50. Since the insulating member 7 is in non-contact with the base 50, the insulating member 7 or the ceramic member 6 can be easily replaced.

While various examples have been described above, various additions, omissions, substitutions and changes may be made without being limited to the examples described above. Elements of the different examples may be combined to form another example.

Here, various examples in the disclosure are described in the following [E1] to [E14].

[E1] A substrate support, comprising:
a support body configured to support an object thereon, the object including a substrate, the support body comprising a dielectric portion and a bias electrode disposed in the dielectric portion, the dielectric portion including an upper surface including a support surface facing the object and a lower surface opposite the upper surface, and the support body providing a first through-hole penetrating from the upper surface to the lower surface;
a base providing a second through-hole communicating with the first through-hole and configured to support the support body thereon; and
a ceramic member that has permeability allowing a heat-transfer gas to pass therethrough and is filled in an upper end of the first through-hole, the ceramic member being positioned to set a distance between a lower end thereof and the bias electrode to be smaller than a distance between an upper end thereof and the bias electrode, in a direction in which a central axis of the first through-hole extends.

[E2] The substrate support according to E1,
wherein the lower end of the ceramic member is positioned above the bias electrode.

[E3] The substrate support according to E2,
wherein the lower end of the ceramic member is positioned at a distance of 0.1 mm or more from the bias electrode in the direction in which the central axis of the first through-hole extends.

[E4] The substrate support according to any one of E1 to E3,
wherein the ceramic member is a porous member or a multi-tube member that provides a plurality of through-holes penetrating from the upper end thereof to the lower end thereof.

[E5] The substrate support according to any one of E1 to E4,
wherein the ceramic member is the porous member, and a ratio of a volume of all pores to a volume of the porous member is 40% or more.

[E6] The substrate support according to any one of E1 to E5,
wherein the ceramic member is made of aluminum oxide or silicon carbide.

[E7] The substrate support according to any one of E1 to E6, further comprising, an insulating member that has an insulating property, is disposed in the first through-hole and the second through-hole, and provides a third through-hole connected to the ceramic member.

[E8] The substrate support according to any one of E1 to E7, further comprising:
a first bonding material that is interposed between the support body and the base and bonds the support body and the base to each other; and
a second bonding material that is interposed between the insulating member and the support body in the first through-hole and bonds the insulating member and the support body to each other.

[E9] The substrate support according to any one of E1 to E8,
wherein a maximum width of the second through-hole is larger than a maximum width of the first through-hole.

[E10] The substrate support according to E9,
wherein a gap is formed between a surface of the base that define the second through-hole and the insulating member, and the insulating member is in non-contact with the base.

[E11] The substrate support according to any one of E7 to E10,
wherein the insulating member is a first insulating member,
the substrate support further comprises a second insulating member that has an insulating property and is disposed in the third through-hole, and the second insulating member provides a gap connected to the ceramic member in the third through-hole.

[E12] The substrate support according to E11,
the second insulating member provides a groove on a surface thereof, the groove spirally extending around a central axis of the third through-hole, and
the gap is formed between a surface of the second insulating member defining the groove and a surface of the first insulating member defining the third through-hole.

[E13] The substrate support according to any one of E1 to E13, wherein the bias electrode is a first electrode, and
the support body further includes a second electrode that is an electrostatic electrode disposed in the dielectric portion.

[E14] The substrate support according to E13,
wherein the second electrode is positioned above the first electrode.

[E15] A plasma processing apparatus, comprising:
a plasma processing chamber; and
the substrate support according to any one of E1 to E14, which is disposed
in the plasma processing chamber.

From the foregoing description, it will be appreciated that various examples of the present disclosure have been described herein for purposes of illustration, and that various modifications may be made without departing from the scope and spirit of the present disclosure. Accordingly, the various examples disclosed herein are not intended to be limiting, with the true scope and spirit being indicated by the following claims.

What is claimed is:

1. A substrate support, comprising:
a support body configured to support an object thereon, the object including a substrate, the support body comprising a dielectric portion and a bias electrode disposed in the dielectric portion, the dielectric portion including an upper surface including a support surface facing the object and a lower surface opposite the upper surface, and the support body providing a first through-hole penetrating from the upper surface to the lower surface;
a base providing a second through-hole communicating with the first through-hole and configured to support the support body thereon; and
a ceramic member that has permeability allowing a heat-transfer gas to pass therethrough and is filled in an upper end of the first through-hole, the ceramic member being positioned to set a distance between a lower end thereof and the bias electrode to be smaller than a distance between an upper end thereof and the bias electrode, in a direction in which a central axis of the first through-hole extends.

2. The substrate support according to claim 1, wherein the lower end of the ceramic member is positioned above the bias electrode.

3. The substrate support according to claim 2, wherein the lower end of the ceramic member is positioned at a distance of 0.1 mm or more from the bias electrode in the direction in which the central axis of the first through-hole extends.

4. The substrate support according to claim 1, wherein the ceramic member is a porous member or a multi-tube member that provides a plurality of through-holes penetrating from the upper end thereof to the lower end thereof.

5. The substrate support according to claim 4, wherein
the ceramic member is the porous member, and
a ratio of a volume of all pores to a volume of the porous member is 40% or more.

6. The substrate support according to claim 1, wherein the ceramic member is made of aluminum oxide or silicon carbide.

7. The substrate support according to claim 1, further comprising an insulating member that has an insulating property, is disposed in the first through-hole and the second through-hole, and provides a third through-hole connected to the ceramic member.

8. The substrate support according to claim 7, further comprising:
a first bonding material that is interposed between the support body and the base and bonds the support body and the base to each other; and
a second bonding material that is interposed between the insulating member and the support body in the first through-hole and bonds the insulating member and the support body to each other.

9. The substrate support according to claim 8, wherein a maximum width of the second through-hole is larger than a maximum width of the first through-hole.

10. The substrate support according to claim 9, wherein a gap is formed between a surface of the base that define the second through-hole and the insulating member, and the insulating member is in non-contact with the base.

11. The substrate support according to claim 7, wherein
the insulating member is a first insulating member,
the substrate support further comprises a second insulating member that has an insulating property and is disposed in the third through-hole, and
the second insulating member provides a gap connected to the ceramic member in the third through-hole.

12. The substrate support according to claim 11, wherein
the second insulating member provides a groove on a surface thereof, the groove spirally extending around a central axis of the third through-hole, and
the gap is formed between a surface of the second insulating member defining the groove and a surface of the first insulating member defining the third through-hole.

13. The substrate support according to claim 1, wherein
the bias electrode is a first electrode, and
the support body further includes a second electrode that is an electrostatic electrode disposed in the dielectric portion.

14. The substrate support according to claim 13, wherein
the second electrode is positioned above the first electrode.

15. A plasma processing apparatus, comprising:
a plasma processing chamber; and
the substrate support according to claim 1, which is disposed in the plasma processing chamber.
